(19) United States
(12) Patent Application Publication
(10) Pub. No.: US 2025/0174483 A1
(43) Pub. Date: May 29, 2025

(54) LOAD LOCK ARRANGEMENTS CONFIGURED FOR PERFORMING PARALLEL PROCESSES, AND ASSOCIATED SYSTEMS AND METHODS

(71) Applicant: ASM IP Holding B.V., Almere (NL)

(72) Inventors: Salam Harb, Scottsdale, AZ (US); Samer Banna, Phoenix, AZ (US); Pradeep Nambiath, Mesa, AZ (US)

(21) Appl. No.: 18/962,111

(22) Filed: Nov. 27, 2024

Related U.S. Application Data
(60) Provisional application No. 63/603,499, filed on Nov. 28, 2023.

(51) Int. Cl. H01L 21/68; H01L 21/67

(52) U.S. Cl. CPC H01L 21/68; H01L 21/67201

(57) ABSTRACT

Load lock arrangements, semiconductor processing systems including such load lock arrangements, and associated methods for performing parallel processes within such load lock arrangement are disclosed. The load lock arrangements disclosed include an alignment assembly disposed within a load lock body and configured for aligning a substrate within the interior of the load lock body while in parallel reducing the pressure within the load lock body.

### CROSS-REFERENCE TO RELATED APPLICATION(S)

This application claims the benefit of U.S. Provisional Application 63/603,499 filed on Nov. 28, 2023, the entire contents of which are incorporated herein by reference.

### FIELD

The present disclosure generally relates to the field of semiconductor processing apparatus, systems, and methods, and to the field of device and integrated circuit manufacture. More particularly, the present disclosure relates to load lock arrangements configured for performing parallel processes, semiconductor processing systems including such load lock arrangements, and associated methods.

### BACKGROUND

Semiconductor processing systems, such as those employing cluster-type platforms, commonly include a front-end connected to a back-end by a load lock chamber, also referred to herein as a load lock arrangement. The front-end generally interfaces the semiconductor processing system to the external environment and typically includes a front-end substrate transfer robot to transfer substrates between the front-end module and the load lock chamber. The back-end typically includes one or more process modules wherein the substrate processing is performed, as well as a back-end substrate transfer chamber including a back-end substrate transfer robot employed to transfer substrates between the load lock chamber and the process modules. The load lock chamber generally couples the back-end of the semiconductor processing system to the front-end of the semiconductor processing system and is typically arranged to isolate the environment maintained in the back-end of the semiconductor processing system from the environment maintained in the front-end of the semiconductor processing system.

Semiconductor processing systems commonly utilize dedicated stand-alone substrate aligners to provide alignment functions and substrate identification functions during semiconductor processing. Such stand-alone substrate aligners are frequently mounted at one end (e.g. on a side) of an equipment front-end module (EFEM) enclosure or the enclosure of a substrate sorter. Positioning of such dedicated substrate aligners on the end of the EFEM can significantly impact substrate transport time and waiting time in order to allow the dedicated substrate aligner(s) to perform substrate alignment. In particular, substrate transport within a cluster-type platform, involving multiple transfers between the various process modules/load lock arrangements, etc., further increases the risk of an undetected substrate misalignment during pick, transfer, and placement of the substrates. If a misalignment of the substrate is not detected and corrective action taken, then there can be an increased risk of substrate breakage. Accordingly, improved load lock arrangements, (including load lock chambers, substrate transfer chambers, substrate handling chambers, and the like), as well as semiconductor processing systems including such improved load lock arrangements, and associated methods are desirable.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to apparatus, systems, and associated methods for performing parallel processes in a load lock arrangement and associated semiconductor processing system. As set forth in more detail below, the apparatus of the present disclosure include load lock arrangements configured for performing parallel processes, including but not limited, substrate alignment operations, substrate positioning operations, and exhaust/vent operations for controlling a pressure in the load lock arrangement.

The embodiment of the present disclosure allow the processes of substrate alignment, substrate positioning, and chamber pump down to be performed in parallel (e.g., simultaneous, or with at least some degree of processing time overlap). This enablement of parallel processing addresses a number of constraints within semiconductor processing systems. For example, the embodiments of the disclosure increase the throughput of substrates through a semiconductor processing system by merging the processing of (a) substrate alignment within a load lock arrangement with (b) reducing the pressure within the load lock arrangement. By performing such processes in parallel, a significant improvement in substrate throughput can be achieved. The embodiments of the present disclosure also enable alignment of substrates under reduced pressure and/or while changing the pressure in a load lock arrangement in cluster-type semiconductor processing systems where substrates commonly undergo multiple transfers between the various process modules and the load lock arrangement. Performing parallel processing employing the load lock arrangements of the present disclosure in cluster-type platforms significantly reduces the risk of substrate misalignment and potential substrate breakage by pre-emptive detection and correction. Further, the embodiments of the disclosure enable controlling the elevation of a substrate within the load lock arrangement (i.e., the raising and lowering of the substrate position) in parallel with alignment and chamber pump down/vent processes further improving processing efficiency and substrate throughput.

In accordance with examples of the disclosure, a load lock arrangement configured for performing parallel processes is provided. An exemplary load lock arrangement includes a load lock body in fluid communication with a vacuum assembly, the vacuum assembly configured for exhaust/vent operations for controlling a pressure in the load lock body. The load lock arrangement further includes an alignment assembly configured to rotate a substrate about a first axis of the load lock body for substrate alignment operations. The alignment assembly includes a rotation module including an alignment stage coupled to a first end of a drive shaft, and a rotation drive disposed outside of the load lock body and coupled to a second end of the drive shaft, the first end and second end of the drive shaft coupled by a feedthrough mechanism. The load lock arrangement further includes, a rotation sensor configured and arranged to sense a rotational alignment of the substrate on the alignment stage through a view port disposed in a wall of the load lock body, and a controller operably connected with the vacuum assembly, the rotation module, and the rotation sensor, to enable parallel alignment operations and exhaust/vent operations within the load lock body. In some embodiments the feedthrough mechanism is a magnetic coupling. In some embodiments the feedthrough mechanism is a ferrofluidic seal including a magnetic fluid disposed between the drive shaft and a drive shaft housing.

In accordance with examples of the disclosure, the load lock arrangement further includes an elevation module configured to elevate the substrate about a second axis of the load lock body for substrate positioning operations. In such examples, the elevation module is connected to the rotation module and includes an elevation drive and an elevation feedthrough seal, the elevation feedthrough seal configured to maintain the pressure within the load lock body when the elevation drive is engaged. In some embodiments, the elevation feedthrough seal is a bellows.

In accordance with examples of the disclosure, the load lock arrangement further includes an elevation sensor for determining the elevation of the alignment stage, the elevation sensor and the elevation module operably connected to the controller to enable substrate positioning operations in parallel with substrate alignment operations, and exhaust/vent operations, all within the load lock body.

In accordance with examples of the disclosure, the load lock arrangement further includes a temperature control plate disposed in the load lock body. In such examples, the elevation sensor, the controller, and the elevation module operate together to control the separation between the alignment stage and the temperature control plate to enable substrate temperature control operations in parallel with substrate alignment operations, and exhaust/vent operations, all within the load lock body.

In accordance with additional examples of the disclosure, a semiconductor processing system is provided. An exemplary semiconductor processing system includes a load lock arrangement which includes a load lock body in fluid communication with a vacuum assembly configured for exhaust/vent operations for controlling a pressure in the load lock body and an alignment assembly configured to rotate a substrate about a first axis of the load lock body for substrate alignment operations. In such examples, the alignment assembly includes a rotation module including an alignment stage coupled to a first end of a drive shaft, and a rotation drive disposed outside of the load lock body and coupled to a second end of the drive shaft, the first end and second end of the drive shaft coupled by a feedthrough mechanism. In such examples, the semiconductor processing system also includes a rotation sensor configured and arranged to sense a rotational alignment of the substrate on the alignment stage through a view port disposed in a wall of the load lock body, and a controller operably connected with the vacuum assembly, the rotation module, and the rotation sensor, to enable parallel alignment operations and exhaust/vent operations within the load lock body. The exemplary semiconductor processing system also includes an equipment front-end module (EFEM) connected to a front face of the load lock body, the EFEM housing a front-end a substrate transfer robot, and a back-end transfer module (BETM) connected to a rear face of the load lock body, the BETM coupling a process module to the load lock body;

In accordance with examples of the disclosure, the semiconductor processing system includes an elevation module configured to elevate the substrate about a second axis of the load lock body for substrate positioning operations. In such examples, the elevation module is connected to the rotation module and includes an elevation drive and an elevation feedthrough seal. In such examples, the elevation feedthrough seal is configured to maintain the pressure within the load lock body when the elevation drive is engaged.

In accordance with examples of the disclosure, the semiconductor processing system includes an elevation sensor for determining an elevation of the alignment stage. In such examples the elevation sensor and the elevation module are operably connected to the controller to enable substrate positioning operations in parallel with substrate alignment operations, and exhaust/vent operations, all within the load lock body.

In accordance with examples of the disclosure, the semiconductor processing system includes a temperature control plate disposed in the load lock body. In such examples, the elevation sensor, the controller, and the elevation module operate together to control the separation between the alignment stage and the temperature control plate to enable substrate temperature control operations in parallel with substrate alignment operations, and exhaust/vent operations, all within the load lock body.

In accordance with examples of the disclosure, the semiconductor processing system includes one or more additional process modules configured in a cluster-type arrangement. In additional examples, the semiconductor processing system also includes one or more additional load lock arrangements, wherein the controller is configured to perform parallel alignment operations, exhaust/vent operations, and substrate positioning operations in the one or more additional load lock arrangements. In additional examples the controller is operably connected with the front-end substrate transfer robot to enable parallel alignment operations, exhaust/vent operations, and front-end substrate transfer robot movement operations.

In accordance with additional examples of the disclosure, methods of performing parallel operations within a load lock arrangement including an alignment assembly are provided. An exemplary method includes (a) transferring a substrate to the load lock arrangement and seating the substrate on an alignment stage of the alignment assembly, the alignment stage being disposed within a load lock body, (b) performing exhaust/vent operations to control a pressure in the load lock body by engaging a vacuum assembly in fluid communication with the load lock body, (c) sensing substrate alignment and generating a misalignment signal by employing a rotation sensor configured and arranged to observe the substrate on the alignment stage through a view port disposed in the load lock body, and (d) aligning the substrate by controlled rotation of the alignment stage in response to the misalignment signal, the rotation of the alignment stage being achieved by engaging a rotation drive disposed outside of the load lock body and coupled to a second end of a drive shaft, a first end of the drive shaft being coupled to the alignment stage. In such examples, the first end and second end of the drive shaft are coupled by a feedthrough mechanism;

In accordance with examples of the disclosure the steps of (b) performing exhaust/vent operations, (c) sensing substrate alignment, and (d) aligning the substrate, are performed at least partially in parallel.

In accordance with examples of the disclosure, the load lock arrangement comprises part of a semiconductor process system in a cluster-type arrangement, and the steps of (b) performing exhaust/vent operations, (c) sensing substrate alignment, and (d) aligning the substrate, are performed a plurality of times at least partially in parallel.

In accordance with examples of the disclosure, exemplary methods also include an additional step (e) comprising, positioning the substrate by controlling the elevation of the alignment stage. In such examples, the elevation of the alignment stage is controlled by an elevation module connected to a rotation module, the elevation module including an elevation drive and an elevation feedthrough seal, the elevation feedthrough seal configured to maintain the pressure within the load lock body when the elevation drive is engaged. In some embodiments, the additional step (e) of positioning the substrate further includes decreasing the separation between the alignment stage and a temperature control plate to enable substrate temperature control operations at least partially in parallel with (b) performing exhaust/vent operations, (c) sensing substrate alignment, and (d) aligning the substrate. In some embodiments, the elevation feedthrough seal comprises a bellows. In some embodiments, the feedthrough mechanism comprises a magnetic coupling or a ferrofluidic seal.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a semiconductor processing system in accordance with one or more embodiments of the disclosure.

FIG. 2 illustrates a load lock arrangement in accordance with one or more embodiments of the disclosure.

FIG. 3 illustrates a method of performing parallel processes within a load lock arrangement in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of apparatus, systems, and methods provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “load lock arrangement” can refer to any chamber arrangement which is configured for the handling, transferring, and/or storage of substrates prior to and/or post processing in a process module (i.e., reactor, reaction chamber, and the like).

As used herein, the terms “processes” and “operations” are used interchangeably.

As used herein, the term “parallel processing”, “parallel processes” as well as operations/processes performed in “parallel” can refer to operations/processes that are performed with at least temporal overlap. For example, parallel processes can refer to operations/processes performed simultaneous, or with at least some operation/processing time overlap.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group Ill-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

As used herein, the term “film” and/or “layer” can used interchangeably and can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate and/or embedded in a device manufactured on that substrate. A film or layer may comprise material or a layer with pinholes and/or isolated islands. A film or layer may be at least partially continuous. A film or layer may be patterned, e.g., subdivided, and may be comprised of a plurality of semiconductor devices.

Various embodiments of the present disclosure relate to load lock arrangements configured for performing parallel processes, semiconductor processing systems including such load lock arrangements, and associated methods for performing parallel operations within a load lock arrangement and semiconductor processing systems including the load lock arrangement.

The throughput of substrates through common semiconductor processing systems is often negatively impacted by the need to return a substrate to the equipment front-end module when a substrate is determined to be misaligned. This negative effect on substrate throughput is amplified further when employing a cluster-type platform for processing substrates as the front-end substrate transfer robot can often be in engaged in transferring misaligned substrate back to the equipment front-end module for realignment rather than performing other operations.

The embodiments of the present disclosure enable a load lock arrangement to perform misalignment detection and correction operations without the need for the front-end substrate transfer robot to be engaged, freeing up the front-end substrate transfer robot to perform other operations. In addition, the load lock arrangements of the present disclosure enable the processes of substrate alignment, load lock pump down/venting, substrate positioning, and substrate cooling/heating to all be performed in parallel, or at least partially in parallel, greatly increasing substrate throughput while decreasing the risk of substrate breakage.

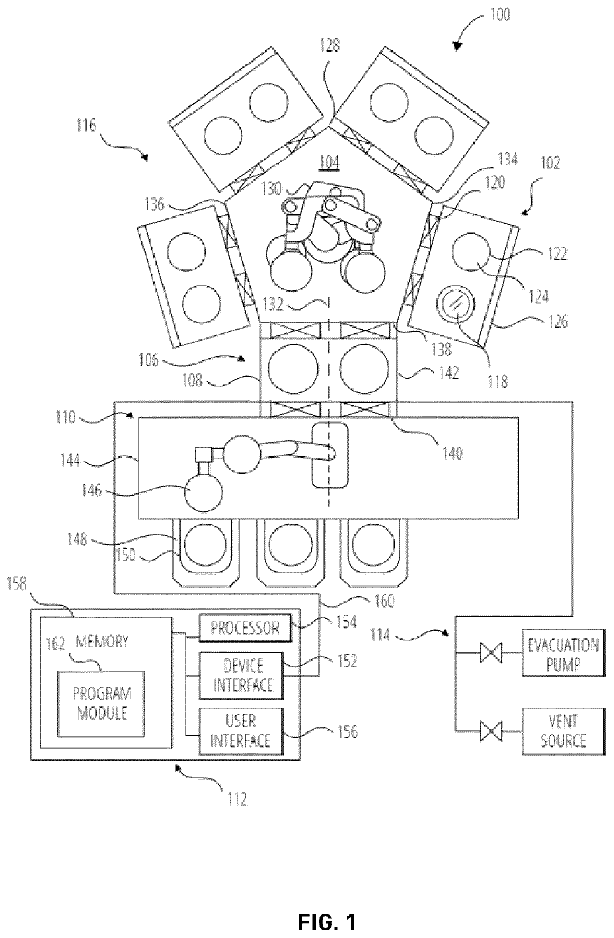

Turning now to the figures, FIG. 1 illustrates a semiconductor processing system 100 of the present disclosure, including a load lock arrangement 106 configured to perform parallel processes. The semiconductor processing system 100 includes a process module 102, a back-end transfer module 104, and a load lock arrangement 106 including load lock body 108. The semiconductor processing system 100 also includes an equipment front-end module (EFEM) 110, a controller 112, and a vacuum assembly 114 including an evacuation pump and venting source. In the illustrated example the semiconductor processing system 100 includes a cluster-type platform 116 with four (4) process modules configured to deposit/etch a material layer onto/from a substrate 118 using deposition and/or etch processes, such as, atomic layer deposition (ALD), chemical vapor deposition (CVD), plasma-enhanced chemical vapor deposition (PECVD), plasma-enhanced atomic layer deposition (PEALD), atomic layer etch (ALEt) processes, chemical vapor etch (CVE) processes, and plasma based dry-etch processes, for example. This is for illustration and description purposes only and is non-limiting. As will be appreciated by those of skill in the art in view of the present disclosure, semiconductor processing systems configured for other material layer deposition/etch operations as well as semiconductor processing systems configured for other processing operations can also benefit from the present disclosure.

The process module 102 is coupled to the back-end transfer module 104 by a process module gate valve 120. The process module 102 includes a process chamber 122, a heater 124, and a reactant source 126. The process chamber 122 is arranged within the process module 102, houses the heater 124, and is configured to flow a precursor or reactant across the substrate 118 while seated on the heater 124 during deposition/etch of a material layer onto/from the substrate 118. The precursor/reactant source 126 is fluidly coupled to the process chamber 122 and configured to provide the precursor/reactant to the process chamber 122 for deposition/etch of the one or more material layers onto/from the substrate 118. The process module gate valve 120 couples the process module 102 to the back-end transfer module 104 and is configured to provide selective communication between the process chamber 122 and the back-end transfer module 104. In this respect it is contemplated that the process module gate valve 120 can be configured to permit transfer of the substrate 118 between the back-end transfer module 104 and the process module 102 before and after deposition of material layer(s) onto the substrate 118.

In accordance with examples of the disclosure, the process chamber 122 may be a first process chamber and the process module 102 may include one or more second process chambers. For example, the process module 102 may be a dual chamber module having two (2) process chambers or a quad chamber module having four (4) process chambers. In accordance with certain examples, the process module gate valve 120 may be a first process module gate valve and the process module 102 may include a second process module gate valve also coupling the process module 102 to the back-end transfer module 104. It is contemplated that, in certain examples, the reactant may include a reactant or a precursor suitable for deposition/etch of a material layer. It is also contemplated that, in accordance with certain examples, the process module 102 includes a plasma unit configured to provide the reactant to the substrate 118 as a suitable plasma. In this respect the process module 102 may be configured to deposit/etch a material layer onto/from the substrate 118 using a plasma-enhanced deposition/etch technique by way of example.

The back-end transfer module 104 is coupled to a rear face 138 of the load lock body 108 and includes a back-end chamber body 128 and a back-end substrate transfer robot 130. The back-end chamber body 128 is arranged along a transfer axis 132. It is contemplated that the back-end substrate transfer robot 130 be arranged within an interior of the back-end chamber body 128 and supported within the back-end chamber body 128 for movement relative to the back-end chamber body 128 for transfer of substrates, e.g., the substrate 118, between the load lock arrangement 106 and the process module 102. In certain examples, the back-end chamber body 128 may have a polygonal shape. In this respect the back-end chamber body 128 may have five sides, fewer than five sides (e.g., a rectangular or square shape), or more than five sides (e.g., a hexagonal shape), and may have the shape of a regular polygon or an irregular polygon.

The equipment front-end module (EFEM) 110 is coupled to a front face 140 of the load lock body 108 and includes an enclosure 144, a front-end substrate transfer robot 146, and one or more load port 148. The enclosure 144 houses the front-end substrate transfer robot 146. The front-end substrate transfer robot 146 is housed within the enclosure 144 for movement relative to the enclosure 144 or transfer of substrates, e.g., the substrate 118, between the one or more load ports 148 and the load lock arrangement 106. The one or more load ports 148 are connected to the enclosure 144 and are configured to seat therein a pod 150 housing one or more substrates, prior to and subsequent to deposition/etch of material layers onto/from the substrates. In certain examples, the pod 150 may include a standard mechanical interface pod. In accordance with certain examples, the pod 150 may include a front-opening unified pod. Although shown and described herein as having three (3) load ports it is to be understood and appreciated that equipment front-end module 110 may include fewer or additional load ports and remain within the scope of the present disclosure.

The controller 112 is operably connected to the semiconductor processing system 100 and includes a device interface 152, a processor 154, a user interface 156, and a memory 158. The device interface 152 couples the processor 154 to the semiconductor processing system 100, for example, through (or over) a wired or wireless link 160. The processor 154 is operably connected to the user interface 156 and is disposed in communication with the memory 158. The memory 158 includes a non-transitory machine-readable medium having a plurality of program module 162 recorded thereon containing instructions that, when read by the processor 154, cause the processor 154 to execute certain operations.

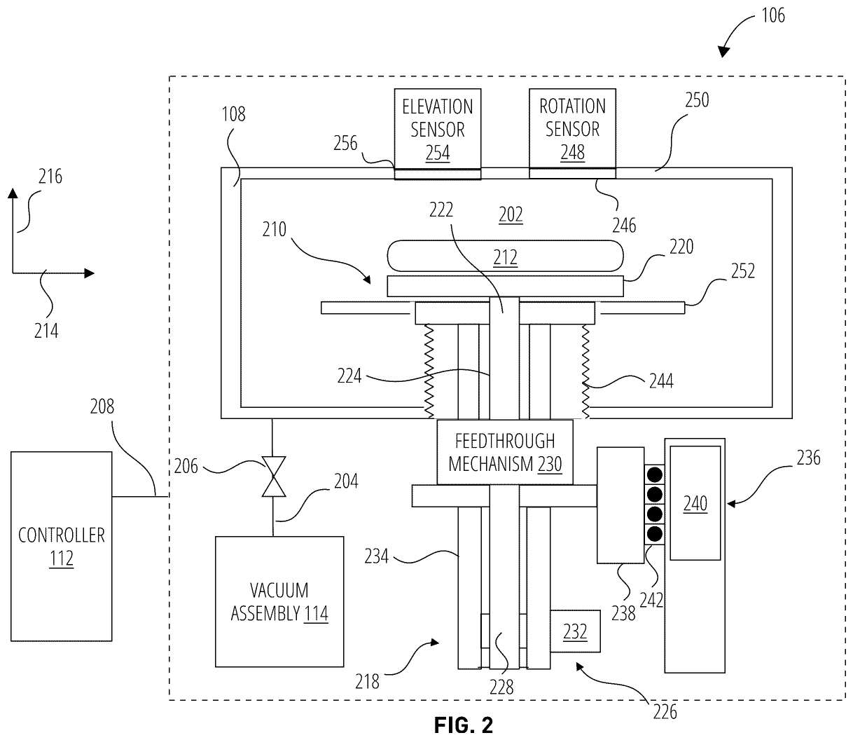

FIG. 2 illustrates an exemplary load lock arrangement 106 in accordance with embodiments of the present disclosure and illustrates a simplified cross-sectional view of an exemplary configuration of the load lock elements of the load lock arrangement 106.

In more detail, the load lock arrangement 106 includes a load lock body 108 with a load lock body interior 202. The load lock arrangement 106 includes a front face configured for coupling with an equipment front-end module and a rear face configured for coupling with a back-end transfer module, as illustrated in FIG. 1.

In accordance with examples of the disclosure, the load lock arrangement 106 (FIG. 2) includes a vacuum assembly 114 in fluid communication with the load lock body 108 by way of vacuum line 204 and vacuum valve 206. The vacuum assembly 114, vacuum line 204, and vacuum valve 206 operate to control the pressure in the load lock body interior 202 by reducing the pressure within the load lock body interior 202, as well venting the load lock body interior 202 to atmosphere when needed.

In accordance with further examples of the disclosure, the load lock arrangement 106 includes a controller 112. In some embodiments, the controller 112 is the same as the controller described with reference to FIG. 1 or in alternative embodiments a separate controller may be employed. In some embodiments, the controller 112 includes the internal controller elements as described with reference to FIG. 1 (e.g., a device interface 152, a processor 154, a user interface 156, and a program module 162) and is operably connected to the load lock arrangement 106. The device interface couples the processor to the load lock arrangement 106, for example, through (or over) a wired or wireless link 208. The processor is operably connected to the user interface and is disposed in communication with the memory. The memory includes a non-transitory machine-readable medium having a plurality of program module recorded thereon containing instructions that, when read by the processor, cause the processor to execute certain operations. Among the operations are operations for correcting substrate misalignment, positioning of substrates, heating/cooling substrates, and exhaust/vent operations in the load lock arrangement 106, as will be described below.

In accordance with examples of the disclosure, the load lock body 108 is connected to vacuum assembly 114 (including the evacuation pump and the vent source, as illustrated in FIG. 1) to allow the load lock arrangement 106 to be transitioned from atmospheric pressure to vacuum (i.e., when pumped-down to a reduced pressure) and back to atmospheric pressure again (i.e., when vented). In this way, the load lock arrangement 106 can be controllably held at a high vacuum (i.e., under reduced pressure) while other modules/regions of a semiconductor processing system (e.g., such as that illustrated in FIG. 1) can be held at atmospheric pressure.

In accordance with examples of the disclosure, the load lock arrangement 106 includes an alignment assembly 210. In some embodiments, the alignment assembly 210 is configured to (a) rotate a substrate 212 about a first axis 214 of the load lock body 108 for substrate alignment operations, and elevate a substrate 212 about a second axis 216 of the load lock body 108 for substrate positioning operations.

In more detail and in accordance with examples of the disclosure, rotation of the substrate 212 about the first axis 214 of the load lock body 108 (i.e., for aligning substrates) is achieved with the rotation module 218 of the alignment assembly 210. In some embodiments, the rotation module 218 comprises an alignment stage 220 upon which the substrate 212 is seated and supported. The alignment stage 220 can comprise a substrate chuck for holding the substrate in place within the load lock body 108. In such examples, the alignment stage 220 can comprise an electrostatic chuck capable of maintaining an electric charge sufficient to hold a substrate in place for an extended period of time. In additional examples, the alignment stage 220 can comprise a vacuum chuck.

In some embodiments, the alignment stage 220 is coupled to a first end 222 of a drive shaft 224. In some embodiments, a rotation drive 226 is coupled to a second end 228 of the drive shaft 224. In such examples, the rotation drive 226 is disposed outside of the load lock body 108. In accordance with examples of the disclosure, the first end 222 of the drive shaft 224 and the second end 228 of the drive shaft 224 are coupled by a feedthrough mechanism 230. In accordance with examples of the disclosure, the rotation drive 226 includes a rotation motor 232 which controllably rotates alignment stage 220 about the central axis of the load lock body 108 by way of the drive shaft 224 and the feedthrough mechanism 230. In such examples, the drive shaft 224 is disposed in a drive shaft housing 234.

In accordance with examples of the disclosure, the rotation module 218 further comprises a feedthrough mechanism 230. The feedthrough mechanism 230 enables the rotation of the alignment stage 220 within the load lock body 108 while maintaining a vacuum in the load lock body interior. In other words, the feedthrough mechanism 230 can maintain a reduced pressure within the load lock body while the process of aligning the substrate 212 is performed in parallel with additional operations. In such examples, the feedthrough mechanism 230 can include, but it not limited to, a magnetic coupling, an elastomer seal, or a ferrofluidic seal. In some embodiments, the feedthrough mechanism 230 comprises a magnetic coupling. In such examples, the first end 222 of the drive shaft 224 and the second end 228 of the drive shaft 224 are not physically connected but coupled together by the magnetic field of the magnetic coupling. In additional examples of the disclosure, the feedthrough mechanism 230 comprises a ferrofluidic seal including a magnetic fluid. In such examples, the magnetic fluid can be disposed between the drive shaft 224 and a drive shaft housing 234.

In accordance with examples of the disclosure, the load lock arrangement 106 further comprises a rotation sensor 248 positioned for sensing the alignment of the substrate 212 seated on the alignment stage 220. In some embodiments, the rotation sensor 248 is disposed outside of the load lock body 108 and is configured and arranged to sense the rotational alignment of the substrate 212 on the alignment stage 220 through a view port 246 disposed in the wall 250 of the load lock body 108. In such examples, the rotation sensor 248 can include one or more optical sensors such as a break-the-beam sensor or a line scan sensor/camera configured to measure/detect a substrate fiducial. Further in such examples, the view port 246 comprises an optically transparent material having optical transparency over at least the portion of the wavelength that is emitted/received by the rotation sensor 248. In accordance with examples of the disclosure, the rotation sensor 248 can be configured and arranged to measure/detect an edge of the substrate and/or to determine one or more predetermined characteristics of the substrate including, for example, such as diameter, radial runout, location of the substrate centerline, location of substrate center. In particular examples, the rotation sensor 248 is configured and arranged to measure/detect a position of an alignment fiducial (e.g. notch/flat, mark or other feature) location on the substrate 212 and determine any misalignment.

In accordance with examples of the disclosure, the rotation sensor 248 senses substrate misalignment by observing the substrate 212 disposed on the alignment stage 220 through the view port 246 disposed in the wall 250 of the load lock body 108. Subsequently. the rotation sensor 248 generates a misalignment signal which is communicated to the controller 112, and from the controller to the rotation module 218. A substrate alignment operation can then be performed by controlled rotation of the alignment stage 220 (based on the misalignment signal) by engaging the rotation drive 226. The controller 112, rotation drive 226 (including the rotation motor 232), and the rotation sensor 248 can operate in a feedback configuration to enable correct realignment of the substrate 212.

In accordance with further examples of the disclosure, positioning operations for elevation control of the substrate 212 about the second axis 216 of the load lock body 108 are achieved with the elevation module 236 of the alignment assembly 210. In such examples, the elevation module can perform as an indexer mechanism for controlling the vertical position of the alignment stage 220 and a substrate 212 seated there on. For example, the elevation module 236 can modify the position (i.e., the vertical location of the substrate 212) within the load lock body for a number of operations including, but not limited to, substrate loading/unloading, and temperature control of the substrate.

In accordance with examples of the disclosure, the elevation module 236 is connected to the rotation module 218 by way of a support element 238. In some embodiments, the elevation module 236 comprises an elevation drive 240 which provides vertical displacement to the rotation module 218 through bearings 242 to support element 238. In some embodiments, the elevation module 236 includes an elevation feedthrough seal 244 configured to maintain the pressure (e.g., a vacuum) within the load lock body 108 when the elevation drive 240 is engaged. In some embodiments, the elevation drive 240 can include any of a variety of drive mechanisms known to those of skill in the art to effectuate linear motion along the second axis 216 including, but not limited to, a stepper motor, a servo motor, a linear motor, or other conventional mechanical linear actuation devices. In some embodiments, the elevation drive 240 comprises a linear motor drive.

In some embodiments, the elevation feedthrough seal 244 comprises a bellows. In such examples, the bellows can comprise an edge welded metal bellows including a plurality of diaphragm plates connected to form a bellows core, the bellows core being connected at either end by welded end fittings to complete the bellows assembly. In such examples, the bellows core is sealed at either end by the end fittings which are in turn sealed to the load lock body 108 and the alignment stage 220 to maintain the pressure within the load lock body 108 as the bellows moves, e.g., as the bellows compresses and expands during movement up and down of the elevation drive 240.

In accordance with examples of the disclosure, the load lock arrangement 106 further comprises an elevation sensor 254 positioned for sensing the elevation (i.e., the vertical location) of the substrate 212 seated on the alignment stage 220. In some embodiments, the elevation sensor 254 is configured to sense the elevation of the alignment stage 220 in an area not concealed by the substrate. In some embodiments the elevation sensor 254 and the rotation sensor 248 comprise a single sensor with the capability to sense both rotation and elevation of the substrate 212/alignment stage 220. In some embodiments, the elevation sensor 254 comprises a position sensor including one or more of an optical sensor (e.g., laser interferometer/laser triangulation sensor, Mickleson interferometer, etc.), a magnetic sensor (e.g., a hall-effect/magnetostrictive sensors), an electrical sensor (e.g., a resistive/capacitive/inductive based sensors), or other known precision position sensors. In examples where the elevation sensor 254 comprises an optical sensor, an additional view port 256 can be disposed in the wall 250 of the load lock body 108.

In accordance with examples of the disclosure, the elevation sensor 254 senses the substrate elevation in the load lock body 108 (e.g., along the second axis 216). Subsequently the elevation sensor 254 generates a position signal which is communicated to the controller 112, and from the controller to the elevation module 236. A substrate positioning operation can then be performed by controlled elevation (i.e., raising or lowering) of the alignment stage 220 (based on the position signal) by engaging the elevation drive 240. The controller 112, the elevation module 236 (including the elevation drive 240), and the elevation sensor 254 can operate in a feedback configuration to enable correct positioning of the substrate 212.

In accordance with further examples of the disclosure, the load lock arrangement 106 further comprises a temperature control plate 252 disposed in the load lock body interior 202. In such examples, the temperature control plate 252 can be disposed proximate to the alignment stage 220. In some embodiments, the temperature control plate 252 can provide substrate heating and/or substrate cooling within the load lock arrangement 106.

As a non-limiting example, in a semiconductor processing systems (such as illustrated in FIG. 1), substrate heating within the load lock arrangement 106 can be implemented to limit processing time within the process module 102 by shortening the time taken to ramp the substrate temperature to a desired process temperature. Alternatively, or additionally, substrate cooling within the load lock arrangement 106 may be implemented to limit processing time within the process modules 102 and/or the time taken prior to transfer to the EFEM. In some embodiments, the temperature control plate 252 is fixed in position in the load lock body interior 202 or alternatively the temperature control plate 252 can be connected to a mechanism to alter the position of the temperature control plate 252 in one or more of the first axis 214 and/or the second axis 216.

In some embodiments, the temperature control plate 252 incorporates heating means and/or cooling means (e.g., via heating elements, cooling channels, and the like) in order to control the temperature of the substrate 212 in the load lock body 108. In some embodiments, the elevation of substrate 212 within the load lock body 108 (i.e., along the second axis 216) can be controlled to decrease the separate between the substrate and the temperature control plate 252 for improved thermal communication between the substrate 212 and the temperature control plate 252. In such examples, the controller 112, the elevation module 236 (including the elevation drive 240), and the elevation sensor 254 operate in a feedback configuration to decrease the separation between the alignment stage 220 (with the substrate seated thereon) and the temperature control plate 252 to enable efficient temperature control of the substrate 212.

The embodiments of the present disclosure also include semiconductor processing systems including the load lock arrangements as described above. In such examples, the load lock arrangement 106 (FIG. 2) can be utilized as part of a semiconductor processing system, such as the exemplary semiconductor processing system 100 of FIG. 1. As the load lock arrangement 106 has been described in detail above, the details relating to the load lock arrangement are not repeated below in the interest of brevity.

In accordance with examples of the disclosure, and with reference to FIG. 1 and FIG. 2, the semiconductor processing system 100 includes a load lock arrangement 106 including a load lock body 108, the load lock body 108 being in fluid communication with the vacuum assembly 114 configured for exhaust/vent operations for controlling the pressure in the load lock body 108. In such examples, an equipment front-end module (EFEM) 110 is connected to a front face 140 of the load lock arrangement 106, the equipment front-end module 110 housing a front-end substrate transfer robot 146, and a back-end transfer module (BETM) 104 is connected to a rear face 138 of the load lock arrangement 106, the back-end transfer module 104 coupling a process module 102 to the load lock arrangement 106.

In some embodiments, the semiconductor processing system 100 further comprising one or more additional process modules 102 configured in a cluster-type arrangement. In accordance with examples of the disclosure, the semiconductor processing system 100 further comprising one or more additional load lock arrangements 106. In such examples, the controller 112 is configured to perform parallel alignment operations, exhaust/vent operations, and substrate positioning operations in the one or more additional load locks. For examples, parallel operations can be performed simultaneously, or least with some degree of process time overlap, in all of the process modules of the semiconductor processing system 100.

In accordance with additional examples of the disclosure, the controller 112 operably connected to the front-end transfer robot 146 to enable parallel alignment operations, exhaust/vent operations, substrate positioning operations, and front-end substrate transfer robot movement operations.

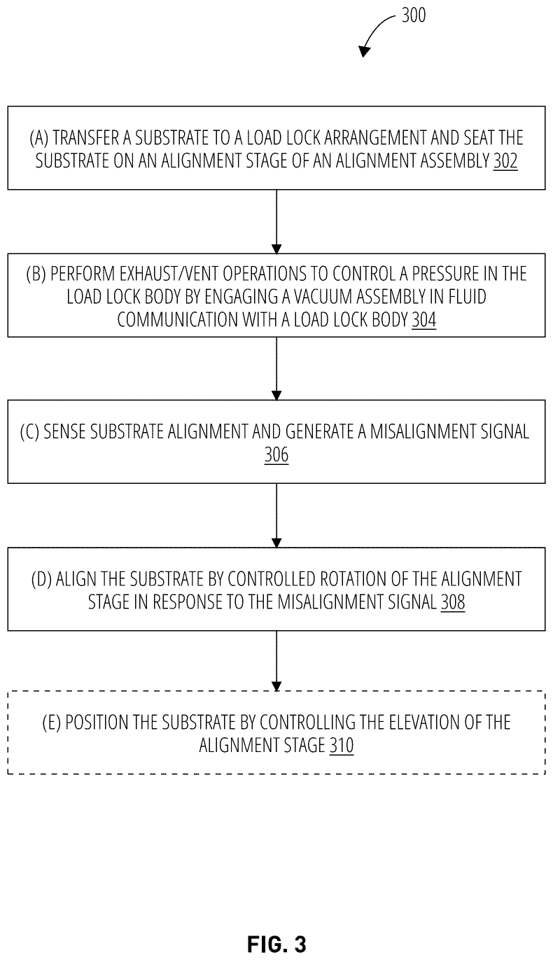

The embodiments of the present disclosure also include methods for performing parallel operation within a load lock arrangement and associated semiconductor processing. In accordance with examples of the disclosure, FIG. 3 illustrates an exemplary method 300 for performing parallel operations within a load lock arrangement and semiconductor processing systems including the load lock arrangement(s).

In accordance with examples of the disclosure, method 300 includes a step (a) 302 which comprises, transferring a substrate to a load lock arrangement and seating the substrate on an alignment stage of the alignment assembly, the alignment stage being disposed within a load lock body, as described in detail herein above.

In accordance with further examples of the disclosure, method 300 further includes a step (b) 304 which comprises, performing exhaust/vent operations to control a pressure in the load lock body by engaging a vacuum assembly in fluid communication with the load lock body, as described in detail herein above.

In accordance with further examples of the disclosure, method 300 further includes a step (c) 306 which comprises, sensing substrate alignment and generating a misalignment signal by employing a rotation sensor configured and arranged to observe the substrate on the alignment stage through a view port disposed in a wall of the load lock body, as described in detail herein above.

In accordance with further examples of the disclosure, method 300 further includes a step (d) 308 which comprises, aligning the substrate by controlled rotation of the alignment stage in response to the misalignment signal, the rotation of the alignment stage being achieved by engaging a rotation drive disposed outside of the load lock body and coupled to a second end of a drive shaft, the first end of the drive shaft being coupled to the alignment stage, wherein the first end and second end of the drive shaft are coupled by a feedthrough mechanism, as described in detail herein above.

In accordance with examples of the disclosure, the steps of (b) performing exhaust/vent operations 304, (c) sensing substrate alignment 306, and (d) aligning the substrate 308, are performed at least partially in parallel. In some embodiments, the load lock arrangement comprises part of a semiconductor process system in a cluster-type arrangement, and the steps of (b) performing exhaust/vent operations 304, (c) sensing substrate alignment 306, and (d) aligning the substrate 308, are performed a plurality of times at least partially in parallel.

In accordance with examples of the disclosure, the method 300 further comprises an optional additional step (e) 310 which comprises, positioning a substrate by controlling the elevation of the alignment stage, wherein the elevation of the alignment stage is controlled by an elevation module connected to the rotation module, the elevation module including an elevation drive and an elevation feedthrough seal, the elevation feedthrough seal configured to maintain the pressure within the load lock body when the elevation drive is engaged, as described in detail herein above. In such examples, the optional additional step (e) 310 of positioning the substrate can further include decreasing the separation between the alignment stage and a temperature control plate to enable substrate temperature control operations at least partially in parallel with the steps of (b) performing exhaust/vent operations 304, (c) sensing substrate alignment 306, and (d) aligning the substrate 308, as described in detail herein above.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A load lock arrangement configured for performing parallel processes, the load lock arrangement comprising:
a load lock body in fluid communication with a vacuum assembly, the vacuum assembly configured for exhaust/vent operations for controlling a pressure in the load lock body;
an alignment assembly configured to rotate a substrate about a first axis of the load lock body for substrate alignment operations, the alignment assembly comprising a rotation module including an alignment stage coupled to a first end of a drive shaft, and a rotation drive disposed outside of the load lock body and coupled to a second end of the drive shaft, the first end and second end of the drive shaft coupled by a feedthrough mechanism;
a rotation sensor configured and arranged to sense a rotational alignment of the substrate on the alignment stage through a view port disposed in a wall of the load lock body; and
a controller operably connected with the vacuum assembly, the rotation module, and the rotation sensor, to enable parallel alignment operations and exhaust/vent operations within the load lock body.

2. The load lock arrangement of claim 1, further comprising an elevation module configured to elevate the substrate about a second axis of the load lock body for substrate positioning operations, the elevation module connected to the rotation module and including an elevation drive and an elevation feedthrough seal, the elevation feedthrough seal configured to maintain the pressure within the load lock body when the elevation drive is engaged.

3. The load lock arrangement of claim 2, wherein the elevation feedthrough seal comprises a bellows.

4. The load lock arrangement of claim 3, further comprising an elevation sensor for determining an elevation of the alignment stage, the elevation sensor and the elevation module operably connected to the controller to enable substrate positioning operations in parallel with substrate alignment operations, and exhaust/vent operations, all within the load lock body.

5. The load lock arrangement of claim 4, further comprising a temperature control plate disposed in the load lock body, wherein the elevation sensor, the controller, and the elevation module operate together to control a separation between the alignment stage and the temperature control plate to enable substrate temperature control operations in parallel with substrate alignment operations, and exhaust/vent operations, all within the load lock body.

6. The load lock arrangement of claim 1, wherein the feedthrough mechanism comprises a magnetic coupling.

7. The load lock arrangement of claim 1, wherein the feedthrough mechanism comprises a ferrofluidic seal including a magnetic fluid disposed between the drive shaft and a drive shaft housing.

8. A semiconductor processing system comprising:
a load lock arrangement comprising;
a load lock body in fluid communication with a vacuum assembly configured for exhaust/vent operations for controlling a pressure in the load lock body;
an alignment assembly configured to rotate a substrate about a first axis of the load lock body for substrate alignment operations, the alignment assembly comprising a rotation module including an alignment stage coupled to a first end of a drive shaft, and a rotation drive disposed outside of the load lock body and coupled to a second end of the drive shaft, the first end and second end of the drive shaft coupled by a feedthrough mechanism;
a rotation sensor configured and arranged to sense a rotational alignment of the substrate on the alignment stage through a view port disposed in a wall of the load lock body;
a controller operably connected with the vacuum assembly, the rotation module, and the rotation sensor, to enable parallel alignment operations and exhaust/vent operations within the load lock body;
an equipment front-end module (EFEM) connected to a front face of the load lock body, the EFEM housing a front-end a substrate transfer robot; and
a back-end transfer module (BETM) connected to a rear face of the load lock body, the BETM coupling a process module to the load lock body.

9. The semiconductor processing system of claim 8, further comprising an elevation module configured to elevate the substrate about a second axis of the load lock body for substrate positioning operations, the elevation module connected to the rotation module and including an elevation drive and an elevation feedthrough seal, the elevation feedthrough seal configured to maintain the pressure within the load lock body when the elevation drive is engaged.

10. The semiconductor processing system of claim 9, further comprising an elevation sensor for determining an elevation of the alignment stage, the elevation sensor and the elevation module operably connected to the controller to enable substrate positioning operations in parallel with substrate alignment operations, and exhaust/vent operations, all within the load lock body.

11. The semiconductor processing system of claim 10, further comprising a temperature control plate disposed in the load lock body, wherein the elevation sensor, the controller, and the elevation module operate together to control a separation between the alignment stage and the temperature control plate to enable substrate temperature control operations in parallel with substrate alignment operations, and exhaust/vent operations, all within the load lock body.

12. The semiconductor processing system of claim 8, further comprising one or more additional process modules configured in a cluster-type arrangement.

13. The semiconductor processing system of claim 12, further comprising one or more additional load lock arrangements, wherein the controller is configured to perform parallel alignment operations, exhaust/vent operations, and substrate positioning operations in the one or more additional load lock arrangements.

14. The semiconductor processing system of claim 12, wherein the controller is operably connected with a front-end substrate transfer robot to enable parallel alignment operations, exhaust/vent operations, and front-end substrate transfer robot movement operations.

15. A method of performing parallel operations within a load lock arrangement including an alignment assembly, the method comprising:
(a) transferring a substrate to the load lock arrangement and seating the substrate on an alignment stage of the alignment assembly, the alignment stage being disposed within a load lock body;
(b) performing exhaust/vent operations to control a pressure in the load lock body by engaging a vacuum assembly in fluid communication with the load lock body;
(c) sensing substrate alignment and generating a misalignment signal by employing a rotation sensor configured and arranged to observe the substrate on the alignment stage through a view port disposed in the load lock body, and
(d) aligning the substrate by controlled rotation of the alignment stage in response to the misalignment signal, the rotation of the alignment stage being achieved by engaging a rotation drive disposed outside of the load lock body and coupled to a second end of a drive shaft, a first end of the drive shaft being coupled to the alignment stage, wherein the first end and the second end of the drive shaft are coupled by a feedthrough mechanism,
wherein the steps of (b) performing exhaust/vent operations, (c) sensing substrate alignment, and (d) aligning the substrate, are performed at least partially in parallel.

16. The method of claim 15, wherein the load lock arrangement comprises part of a semiconductor process system in a cluster-type arrangement, and the steps of (b) performing exhaust/vent operations, (c) sensing substrate alignment, and (d) aligning the substrate, are performed a plurality of times at least partially in parallel.

17. The method of claim 15, further comprising an additional step (e) comprising, positioning the substrate by controlling the elevation of the alignment stage, wherein the elevation of the alignment stage is controlled by an elevation module connected to a rotation module, the elevation module including an elevation drive and an elevation feedthrough seal, the elevation feedthrough seal configured to maintain the pressure within the load lock body when the elevation drive is engaged.

18. The method of claim 17, wherein the additional step (e) of positioning the substrate further comprises decreasing the separation between the alignment stage and a temperature control plate to enable substrate temperature control operations at least partially in parallel with (b) performing exhaust/vent operations, (c) sensing substrate alignment, and (d) aligning the substrate.

19. The method of claim 17, wherein the elevation feedthrough seal comprises a bellows.

20. The method of claim 15, wherein the feedthrough mechanism comprises a magnetic coupling or a ferrofluidic seal.
